(19) United States
(12) Patent Application Publication
(10) Pub. No.: US 2008/0283897 A1
(43) Pub. Date: Nov. 20, 2008

(54) FLASH MEMORY DEVICE AND FABRICATION METHOD THEREOF

(75) Inventors: Yu-Sheng Ding, Taoyuan County (TW); Ching-Nan Hsiao, Kaohsiung County (TW); Chung-Lin Huang, Taoyuan County (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/857,978

(22) Filed: Sep. 19, 2007

(30) Foreign Application Priority Data
May 18, 2007 (TW) TW96117763

(51) Int. Cl. H01L 29/788; H01L 21/336

(52) U.S. Cl. 257/316; 438/266; 257/E29.3; 257/E21.422

(57) ABSTRACT

The invention provides a flash memory device and a method for fabricating thereof. The device comprises a gate stack layer of a gate dielectric layer and a gate polysilicon layer formed on a substrate, a stack layer comprising a floating polysilicon layer and gate spacer formed on the sidewall of the gate stack layer. A metal layer is formed on the gate stack layer and is utilized in place of a portion of the gate polysilicon layer. Because the metal layer has relatively high conductivity and is electrically connected to a metal plug later formed, current velocity of the device is increased to improve performance.

### BACKGROUND OF THE INVENTION

1. Field of the Invention

The invention relates to flash memory devices, and more particularly to a flash memory device having relatively high current velocity and a fabrication method thereof.

2. Description of the Related Art

With the continuing development of advanced technology and popularity of electronic devices, such as computers, mobile phones and personal digital assistants (PDA), higher performance of semiconductor devices have become more and more important.

FIG. 1 is a cross section of a conventional flash memory device. As shown in FIG. 1, a substrate 2 is provided with a stack layer comprising a floating polysilicon layer 4, dielectric layer 6 and gate polysilicon layer 8 formed thereon. A doped region 12 is formed in the substrate adjacent to the stack layer and a tungsten metal layer 10 is deposited on the gate polysilicon layer 8. Because the gate polysilicon layer 8, utilized to electrically connect to the tungsten metal layer 10, has relatively low conductivity, device performance is decreased. Moreover, fabrication yield is hindered during fabrication of the device because a rapid thermal annealing (RTA) step for the doped region 12 is executed after doping the gate polysilicon layer 8. Specifically, penetration of the dopant from the gate polysilicon layer 8 to the dielectric layer 6 easily occurs and results in device failure.

Thus, a flash memory device having relatively high current velocity and ameliorating the described problems is needed.

### BRIEF SUMMARY OF INVENTION

Accordingly, the invention provides a flash memory device. An exemplary embodiment of the device comprises a gate stack layer formed on a substrate, a polysilicon formed on the sidewalls of the gate stack layer, a gate spacer stacked on the polysilicon layer and adjacent to the sidewall of the gate stack layer, and a metal layer formed on the gate stack layer.

For the device, the metal layer, having relatively high conductivity, can be in place of the traditional doped polysilicon layer to electrically connect to a metal plug later formed. Thus, increasing current velocity to improve performance of the device.

Also, the invention provides a method for fabricating a flash memory device. The method comprises forming a gate stack layer, comprising a gate dielectric layer and a gate polysilicon, on a substrate. A hard mask layer is formed on the gate stack layer. A stack layer, comprising a floating polysilicon layer and a gate spacer layer, is formed on the sidewall of the gate stack layer. After removing the hard mask layer, a recess is then formed on the gate stack layer. A dopant is implanted into the gate polysilicon. A metal layer is formed in the recess on the gate stack layer. Because the metal layer can be directly formed in the recess on the gate stack layer without extra steps, such as photolithography and etching, fabrication is simplified and costs are reduced.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is cross section of a conventional flash memory device;

FIGS. 2A through 2D are cross sections illustrating a method for fabricating a flash memory device according to a first embodiment of the invention;

FIGS. 3A through 3D are cross sections illustrating a method for fabricating a flash memory device according to a second embodiment of the invention;

FIGS. 4A through 4D are cross sections illustrating a method for fabricating a flash memory device according to a third embodiment of the invention; and

FIG. 5 is a flow chart of a method for fabricating a flash memory device according to several embodiments of the invention.

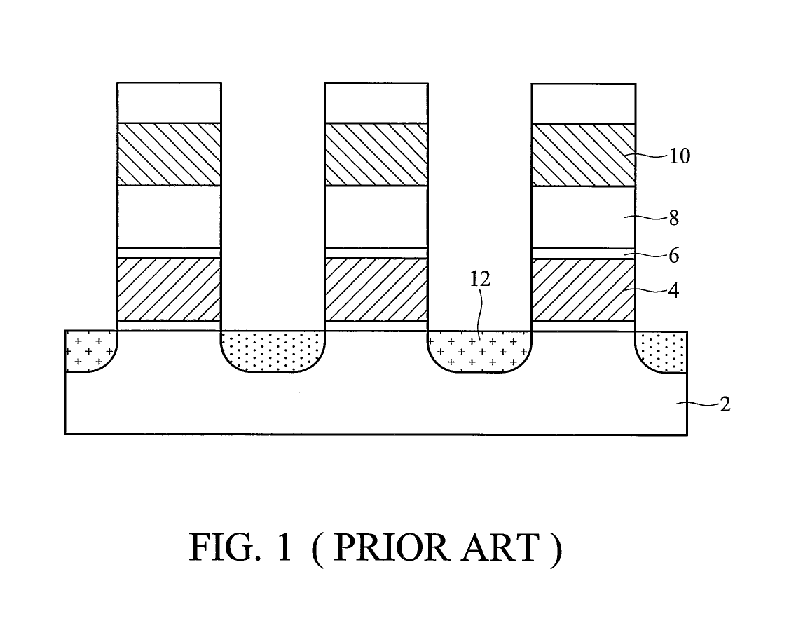

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

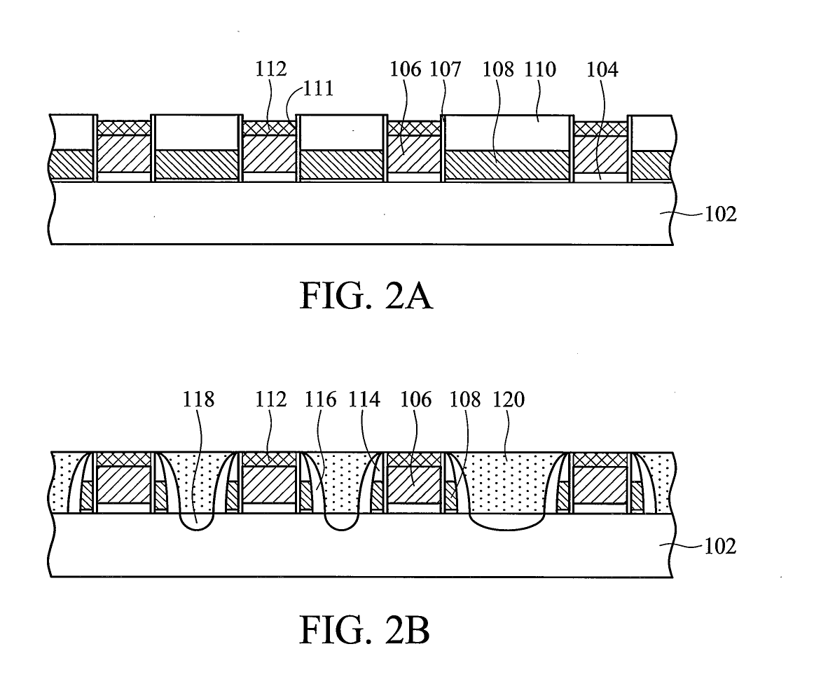

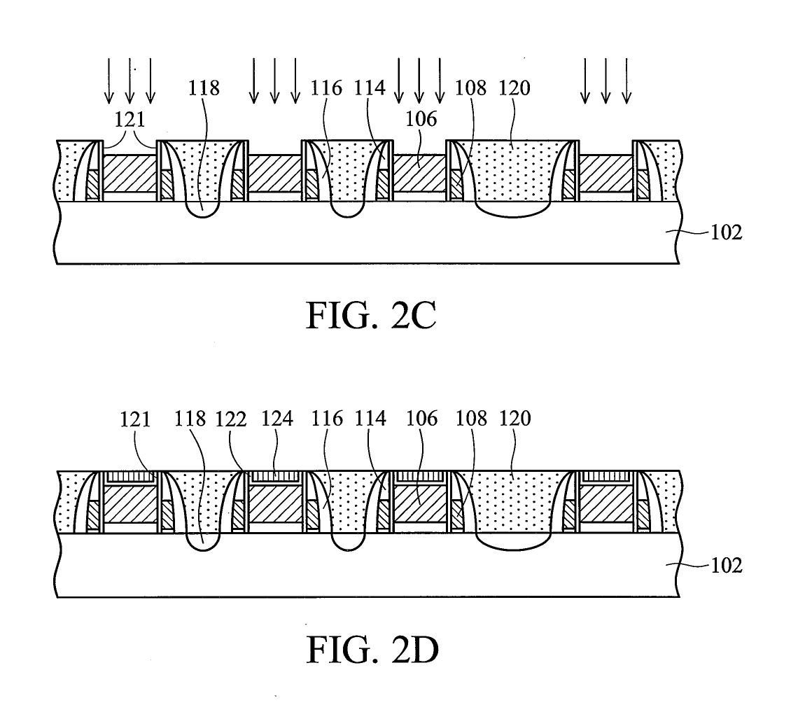

Referring to FIGS. 2A through 2D, cross sections illustrating a method for fabricating a flash memory device according to a first embodiment of the invention are shown. In FIG. 2A, a substrate 102 is provided with a gate dielectric layer 104 and a gate polysilicon layer 106 sequentially formed thereon. The gate polysilicon layer 106 can serve as a control gate (GC) of the flash memory device later formed, and also be referred to as a control gate. The gate polysilicon layer 106 is stacked on the gate dielectric layer 104 to construct a gate stack layer. A dielectric layer 107, for example a triple layer made of oxide layer, nitride layer and oxide layer (ONO), is formed on the sidewalls of the gate stack layer. A floating polysilicon layer 108, also referred to as a flash polysilicon, and an insulating layer 110 is sequentially formed on the substrate 102 close to the dielectric layer 107.

Next, a hard mask layer 112 is formed on the gate polysilicon layer 106 to protect the gate polysilicon layer 106 from a following etching step. In some embodiments, the reason for etching the gate polysilicon layer 106 by an etch-back step is to remove a portion of the gate polysilicon layer 106 and form a recess 111. Thereafter, a layer (not shown), such as silicon nitride or silicon oxide, is conformally formed on the substrate 102 and covers the gate polysilicon layer 106, dielectric layer 107 and insulating layer 110. A portion of the layer is removed by chemical mechanical polishing (CMP) to form the hard mask layer 112 in the recess 111 on the gate polysilicon layer 106. Specifically, the removed portion of the gate polysilicon layer 106 is replaced by the hard mask layer 112. After chemical mechanical polishing, an etch-back step to the hard mask layer 112 is performed to make the top surface of hard mask layer 112 substantially lower than the top surface of the insulating layer 110.

Referring to FIG. 2B, a gate spacer 114 is formed on the floating polysilicon layer 108 to form a stack layer. In one embodiment, after the insulating layer is removed, a layer (not shown) is conformally formed on the substrate 102. Next, the layer and the floating polysilicon layer 108 is partially removed to form the gate spacer 114 stacked on the floating polysilicon layer 108 and expose the surface of a portion of the substrate 102. A barrier layer 116, such as silicon oxide, is formed on the sidewalls of the stack layer comprising the floating polysilicon layer 108 and the gate spacer 114. A doped region 118 is then formed in the substrate 102 adjacent to the barrier layer 116 by doping. After doping, a rapid thermal annealing (RTA) step is optionally performed to diffuse the doped region 118 further into the substrate 102. The doped region 118 serves as a source/drain region of the flash memory device later formed.

Note that because the hard mask layer 112 is made of a material having a etch selectivity different from the gate spacer 114, the hard mask layer 112 can serve as a protective layer for the gate polysilicon layer 106 during the etching step for forming the gate spacer 114. For example, in the first embodiment, the gate spacer 114 may be made of silicon oxide and the hard mask layer 112 may be made of silicon nitride. Additionally, the floating polysilicon layer 108 can serve as a floating gate of the flash memory device later formed.

As shown in FIG. 2B, an interlayer dielectric (ILD) 120 is formed on the substrate 102 and is in contact with the doped region 118. In some embodiments, a layer (not shown), such as silicon oxide (SiO), is formed on the substrate 102 by, for example sub-atmospheric chemical vapor deposition (SACVD), plasma-enhanced chemical vapor deposition (PECVD) using a gas comprising tetraethyl-orthosilicate (TEOS), or any other suitable manner. Next, grinding the layer by a chemical mechanical polishing (CMP) is executed to expose the top surface of the hard mask layer 112. In another embodiment, the layer may be formed by plasma-enhanced chemical vapor deposition subsequent to sub-atmospheric chemical vapor deposition.

Note that the hard mask layer 112, made of silicon nitride according to the first embodiment, may function as a stop layer for chemical mechanical polishing.

As shown in FIG. 2C, after the hard mask layer 112 has been removed, a dopant is implanted into the gate polysilicon layer 106. In one embodiment, the hard mask layer 112 is removed by, for example wet-etching or dry-etching to form a recess 121 on the gate polysilicon layer 106. Next, a patterned photoresist (not shown) is formed on the interlayer dielectric 120 and exposes the gate polysilicon layer 106. Thereafter, the dopant such as boron ion is implanted into the exposed gate polysilicon layer 106, as shown arrow in FIG. 2C. While the doping step has been executed, the patterned photoresist is removed.

Note that for the fabrication method of the flash memory device according to the first embodiment, because the doping step for the gate polysilicon layer is executed after the rapid thermal annealing step for the doped region (source/drain region), flash memory device failure caused by penetration of the dopant from the gate polysilicon layer to the gate dielectric layer, is avoided.

In FIG. 2D, an adhesive promoter layer 122 is formed in the recess 121. In one embodiment, the adhesive promoter layer 122 such as a composite layer of titanium and titanium nitride (Ti/TiN), is conformally formed on the substrate 102 by sputtering or any other suitable manner.

Next, a metal layer 124 is formed in the recess 121. In some embodiments, a metal material layer, such as tungsten (W), is conformally formed on the substrate 102 by, sputtering or any other suitable manner. Then, performing a chemical mechanical polishing (CMP), a portion of the metal material layer and a portion of the composite layer of titanium and titanium nitride are removed to expose the top surface of the interlayer dielectric 120 and form the metal layer 124 and the adhesive promoter layer 122 in the recess 121. After the described steps, the flash memory device according to the first embodiment, as shown in FIG. 2D, is complete.

Note that because the recess 121 can be fabricated on the gate polysilicon layer 106 prior to forming the metal layer 124, the metal layer 124 can be directly filled in the recess 121 without extra steps such as photolithography and etching.

When the described steps have been performed, a metal plug (not shown) can be formed over the substrate and electrically connected to the metal layer 124 on the gate polysilicon layer 106 by methods well-known in the art.

Note that for the flash memory device according to the first embodiment, because the metal layer such as tungsten, which has relatively high conductivity, is utilized in place of the traditional doped polysilicon layer to electrically connect to the metal plug later formed, current velocity of the flash memory device is increased to improve its performance. Moreover, the metal layer can be directly formed in the recess on the gate polysilicon layer without extra steps such as photolithography and etching. Thus, fabrication process is simplified and costs are reduced.

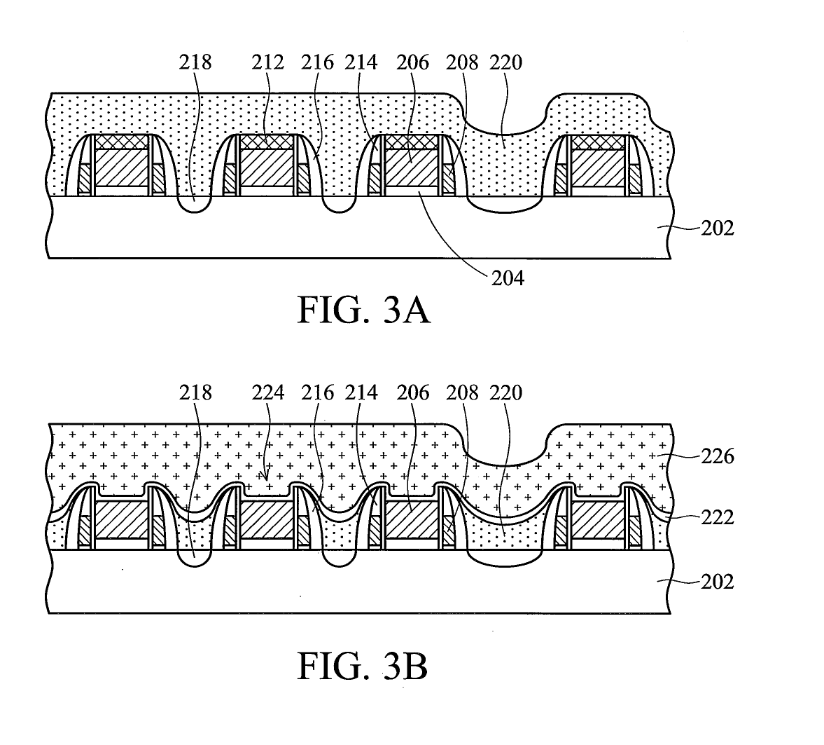

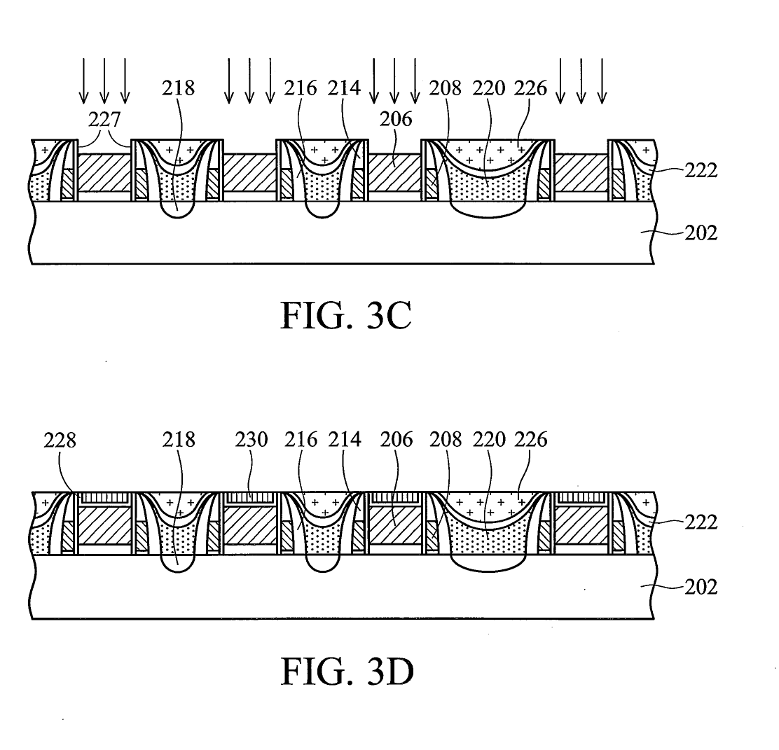

FIGS. 3A through 3D are cross sections illustrating a method for fabricating a flash memory device according to a second embodiment. In FIG. 3A, a gate stack layer comprising a gate dielectric layer 204 and a gate polysilicon layer 206 is formed on a substrate 202. Next, a floating polysilicon layer 208 is formed on the sidewalls of the gate stack layer followed by stacking a gate spacer 214 thereon. A hard mask layer 212 is formed on the gate stack layer. A barrier layer 216 is formed on the sidewalls of the stack layer comprising the gate spacer 214 and floating polysilicon layer 208, and then a doped region 218 is formed in the substrate 202 adjacent to the barrier layer 216, as shown in FIG. 3A. Formations, materials and descriptions of the elements may be similar to that in the first embodiment, thus, further descriptions are not provided for brevity.

Note, compared to the first embodiment, the hard mask layer 212 in the second embodiment is made of silicon oxide and the gate spacer 214 is made of silicon nitride. Similar to the first embodiment, a portion of the gate polysilicon layer 206 is removed followed by forming the hard mask layer 212 on the gate polysilicon layer 206. Moreover, because the hard mask layer 212, such as silicon oxide, has an etch selectivity which differs from that of the gate spacer 214 such as silicon nitride, the hard mask layer 212 can serve as a protective layer for the gate polysilicon layer 206 from the etching steps for forming the gate spacer 214 and the floating polysilicon layer 208.

Referring to FIG. 3A, a dielectric layer 220 is formed on the substrate 202. In one embodiment, the dielectric layer 220 such as silicon oxide is formed on the substrate 202 by sub-atmospheric chemical vapor deposition. Next, the hard mask layer 212 such as silicon oxide is removed by, for example etch-back to form a recess 224 on the gate polysilicon layer 206. Note that because the hard mask layer 212 is made of a material similar to that of the dielectric layer 220, a portion of the dielectric layer 220 is removed during etch-back for removing the hard mask layer 212.

It is appreciated that the gate structure (also the gate stack layer) on the substrate 202 has a very high integration, so that a void (not shown) is formed in the dielectric layer 220 between the gate structures. A recessed portion is formed on the dielectric layer 220 between the gate structures during the removal of the hard mask layer, as shown in FIG. 3B.

Referring to FIG. 3B, a polishing stop layer 222 such as silicon nitride is formed on the substrate 202 and covers the gate polysilicon layer 206 and dielectric layer 220. Next, an interlayer dielectric 226 such as silicon oxide is formed on the substrate 202 by, sub-atmospheric chemical deposition to fill in the recess portion on the dielectric layer 220 between the gate structures.

In FIG. 3C, a chemical mechanical polishing (CMP) process is executed until exposing the polishing stop layer 222 to remove a portion of the interlayer dielectric 226. Then, the exposed polishing stop layer 222 is removed by etch-back to expose the top surface of the gate polysilicon layer 206. Another etch-back step is further executed to remove a portion of the gate polysilicon layer 206 and form a recess 227 on the gate polysilicon layer 206.

After the gate polysilicon layer 206 has been exposed, a dopant such as boron ion is then implanted into the gate polysilicon layer 206. Because the doping for the gate polysilicon layer can be executed after the rapid thermal annealing step for the doped region 218 (also the source/drain region), flash memory device failure, caused by rapid thermal annealing in which induces penetration of the dopant from the gate polysilicon layer to the gate dielectric layer is avoided.

Referring to FIG. 3D, an adhesive promoter layer 228 and a metal layer 230 is sequentially formed in the recess 227 (shown in FIG. 3C). Thus, completing the flash memory device according to the second embodiment of the invention. Formations, materials, and descriptions of the adhesive promoter layer 228 and the metal layer 230 may be similar to that in the first embodiment, thus, further descriptions will not be provided for brevity. Meanwhile, similar to the first embodiment, when the described steps according to the second embodiment have been performed, a metal plug (not shown) may also be formed over the substrate 202 and electrically connect to the metal layer 230 such as tungsten on the gate polysilicon layer 206.

Note, for the flash memory device according to the second embodiment, because the traditional doped polysilicon layer is replaced by the metal layer, such as tungsten, which has relatively high conductivity and electrically connects to the metal plug later formed, current velocity of the flash memory device is thus increased and performance is improved. Moreover, the metal layer can directly be formed in the recess on the gate polysilicon layer without photolithography and etching, as such fabrication process is simplified and costs are reduced.

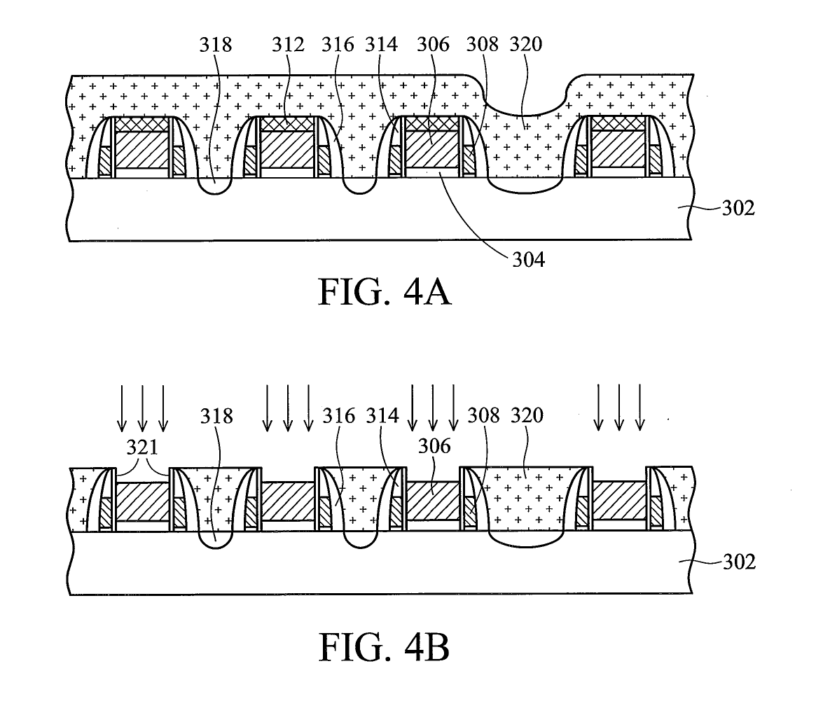

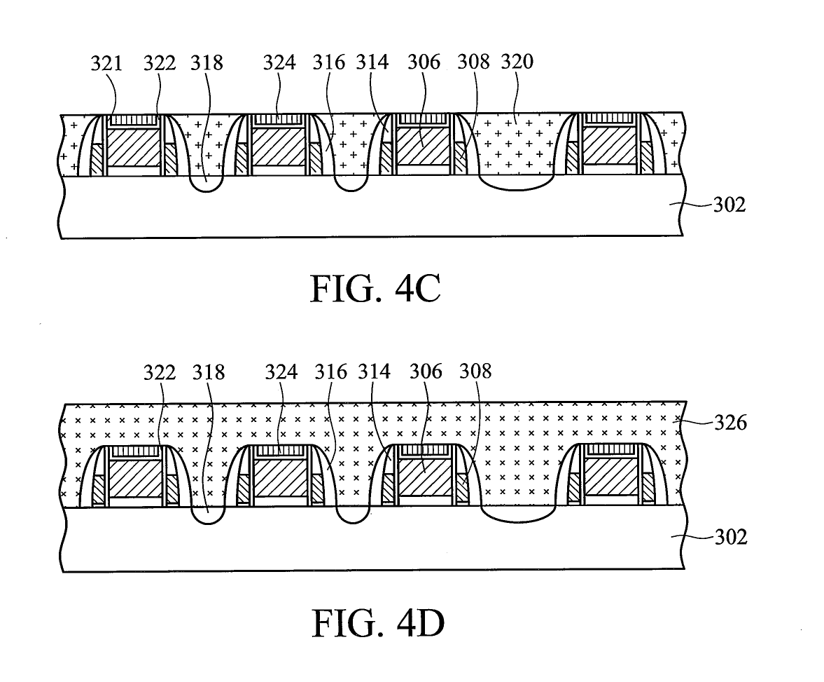

FIGS. 4A through 4D are cross sections illustrating a method for fabricating a flash memory device according to a third embodiment. Referring to FIG. 4A, a gate stack layer comprising a gate dielectric layer 304 and a gate polysilicon layer 306 is formed on the substrate 302. Next, a floating polysilicon layer 308 is formed on the sidewalls of the gate stack layer and a gate spacer 314 is stacked thereon. A hard mask layer 316 is formed on the gate stack layer. A barrier layer 316 is formed on the sidewalls of the gate spacer 314 and the floating polysilicon layer 308 followed by forming a doped region 318 in the substrate 302 adjacent to the barrier layer 316.

In the third embodiment, the hard mask layer 312 may be made of a material such as silicon oxide and the gate spacer 314 may be silicon nitride, which is the same as the material in the second embodiment.

In FIG. 4A, a polysilicon layer 320 is formed on the substrate 302. In one embodiment, the polysilicon layer 320 is formed by chemical vapor deposition (CVD) or any other suitable manner. Next, a portion of the polysilicon layer 320 is removed by chemical mechanical polishing to expose the top surface of the hard mask layer 312.

Referring to FIG. 4B, the hard mask layer 312 is removed by etching to form a recess 321 and expose the gate polysilicon layer 306. Because the hard mask layer 312, such as silicon oxide, has an etch selectivity different from that of the polysilicon layer 320, the polysilicon layer 320 is not etched during the etching step for removing the hard mask layer 312. After the hard mask layer 312 has been removed, a dopant is implanted into the gate polysilicon layer 306 to serve as a control gate of the flash memory device later formed.

Referring to FIG. 4C, an adhesive promoter layer 322 and a metal layer 324 is sequentially formed in the recess 321. In one embodiment, a composite layer (not shown), comprising titanium (Ti) and titanium nitride (TiN) is conformally deposited on the substrate 302 and covers the polysilicon layer 320. A metal material layer (not shown) such as tungsten is formed on the composite layer. The metal material layer and the composite layer are partially removed by chemical mechanical polishing, until the top surface of the polysilicon layer 320 is exposed, to form the adhesive promoter layer 322 and the metal layer 324 inside the recess 321.

As shown in FIG. 4D, after the polysilicon layer 320 has been removed, an interlayer dielectric 326 is conformally deposited on the substrate 302 to complete fabrication of the flash memory device according to the third embodiment.

In another embodiment, prior to removing the polysilicon layer 320, an etching step is optionally executed to remove metal silicide, such as titanium silicide (TiSi2), which is produced by the polysilicon layer 320 reacting with titanium of the adhesive promoter layer 322.

Similar to the first and the second embodiment, for the flash memory device in the third embodiment, tungsten metal layer, which has relatively high conductivity, is utilized in place of traditional doped polysilicon layer to electrically connect the metal plug which is later formed. Accordingly, current velocity of the flash memory device is increased to improve its performance. Furthermore, the metal layer can be directly formed in the recess on the gate polysilicon layer without photolithography and etching, thus, simplifying fabrication and reducing costs.

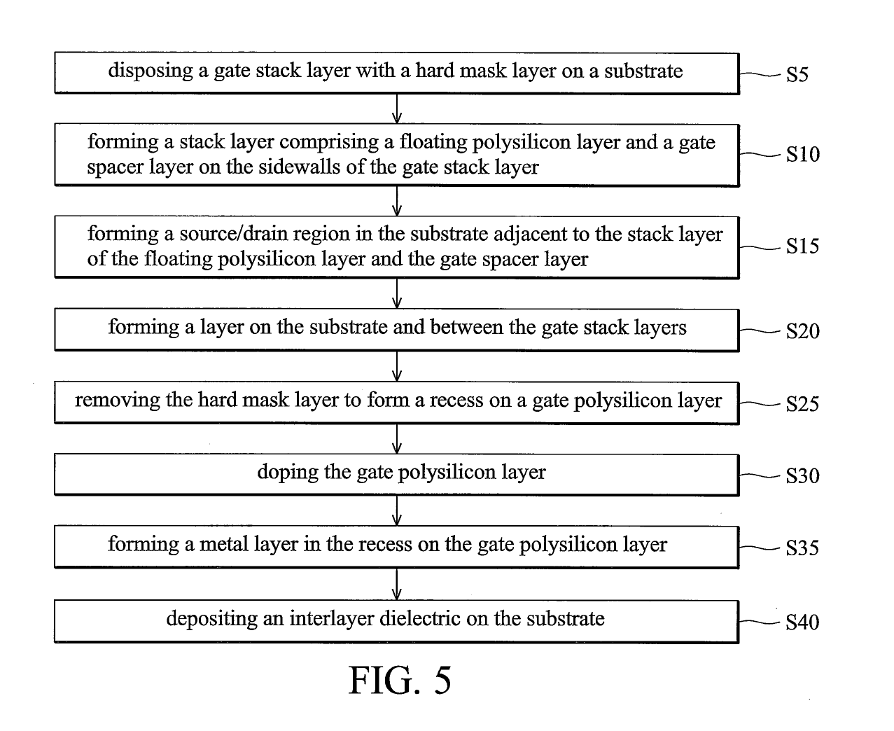

FIG. 5 is a flow chart illustrating a method for fabricating a flash memory device according to several embodiments of the invention. A gate stack layer with a hard mask layer is disposed on a substrate, as shown in step S5, and the gate stack layer comprises a gate dielectric layer and a gate polysilicon layer. Next, a stack layer comprising a floating polysilicon layer, also referred to as a flash polysilicon layer, and a gate spacer is formed on the sidewalls of the gate stack layer, as shown in step S10. A source/drain region is formed in the substrate adjacent to the stack layer comprising the floating polysilicon layer and the gate spacer layer, as shown in step S15. A layer is formed on the substrate and is filled between the gate structures, as shown in step S20. The hard mask layer is removed to form a recess on the gate polysilicon layer, as shown in step S25. Doping the gate polysilicon layer is executed, as shown in step S30. A metal layer is formed in the recess on the gate polysilicon layer, as shown in step S35. An interlayer dielectric is deposited on the substrate, as shown in step S40. After performing the described steps, a flash memory device, having the metal layer in place of a doped polysilicon layer with electrical connection with a metal plug according to several embodiments of the invention, is complete.

Note that because the step for doping the gate polysilicon layer is executed after the source/drain region has been formed, the penetration of the dopant from the gate polysilicon layer to the gate dielectric layer caused by the rapid thermal annealing step for formation of the source/drain region, is avoided to improve fabrication yield. Moreover, the metal layer can be directly formed in the recess on the gate polysilicon layer without photolithography and etching, thus, simplifying fabrication process and reducing costs.

A flash memory device according to several embodiments of the invention is fabricated. In the flash memory device, a gate stack layer comprising a gate dielectric layer and a second polysilicon layer (also referred to as a gate polysilicon), is formed on a substrate. A stack layer comprising a gate spacer and a first polysilicon layer (also referred to as a floating polysilicon layer), is formed on the sidewalls of the gate stack layer. A metal layer is formed on the gate stack layer. Because the metal layer, which has relatively high conductivity, is utilized in place of the traditional doped polysilicon layer to electrically connect to the metal plug later formed, current velocity of the flash memory device is increased to improve its performance.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A flash memory device, comprising:
a gate stack layer formed on a substrate;
a first polysilicon layer formed on at least one sidewall of the gate stack layer;
a gate spacer overlying the first polysilicon layer and adjacent to the sidewall of the gate stack layer; and
a metal layer formed on the gate stack layer.

2. The flash memory device as claimed in claim 1, further comprising a doped region formed in the substrate adjacent to the gate stack layer.

3. The flash memory device as claimed in claim 1, further comprising a barrier layer formed on a sidewall of the first polysilicon layer and a sidewall of the gate stack layer.

4. The flash memory device as claimed in claim 1, wherein the gate stack layer comprises:
a gate dielectric layer formed on the substrate; and
a second polysilicon layer formed on the gate dielectric layer.

5. The flash memory device as claimed in claim 1, further comprising a dielectric layer formed between the gate stack layer and a stack layer of the gate spacer and the first polysilicon layer.

6. The flash memory device as claimed in claim 5, wherein the dielectric layer comprises a triple layer of oxide layer, nitride layer and oxide layer.

7. The flash memory device as claimed in claim 1, wherein the metal layer comprises tungsten.

8. The flash memory device as claimed in claim 1, further comprises an adhesive promoter layer formed between the metal layer and the gate stack layer.

9. The flash memory device as claimed in claim 8, wherein the adhesive promoter layer comprises a composite layer of titanium and titanium nitride.

10. A method for fabricating a flash memory device, comprising:
forming a gate stack layer on a substrate;
forming a hard mask on the gate stack layer;
forming a stack layer comprising a polysilicon layer and a gate spacer layer, on a sidewall of the gate stack layer;
removing the hard mask layer to form a first recess on the gate stack layer; and
forming a metal layer in the first recess on the gate stack layer.

11. The method as claimed in claim 10, wherein forming the hard mask comprises:
removing a portion of the gate stack layer to form a second recess; and
forming the hard mask layer in the second recess.

12. The method as claimed in claim 10, further comprising forming a barrier layer on a sidewall of the stack layer comprising the polysilicon layer and the gate spacer.

13. The method as claimed in claim 12, further comprising forming a doped region in the substrate adjacent to the barrier layer.

14. The method as claimed in claim 10, further comprising forming a layer on the substrate prior to removing the hard mask layer.

15. The method as claimed in claim 10, further comprising implanting a dopant in the gate stack layer after removing the hard mask layer.

16. The method as claimed in claim 10, further comprising forming an adhesive promoter layer in the first recess prior to forming the metal layer.

17. The method as claimed in claim 10, wherein forming the metal layer comprises:
depositing a metal material layer on the substrate; and
removing a portion of the metal material layer to form the metal layer in the first recess.

18. The method as claimed in claim 17, wherein the metal material layer is deposited by sputtering.

19. The method as claimed in claim 17, wherein the portion of metal material layer is removed by chemical mechanical polishing.

20. The method as claimed in claim 10, further comprising covering an interlayer dielectric on the substrate after forming the metal layer.
